(19) United States
(12) Patent Application Publication
(10) Pub. No.: US 2022/0183196 A1
(43) Pub. Date: Jun. 9, 2022

(54) APPARATUS AND METHOD FOR MANUFACTURING DISPLAY DEVICE

(71) Applicant: SAMSUNG DISPLAY CO., LTD., Yongin-si (KR)

(72) Inventors: DONGWOO KIM, Yongin-si (KR); Jungmin Lee, Yongin-si (KR); Myunggil Choi, Yongin-si (KR)

(21) Appl. No.: 17/394,273

(22) Filed: Aug. 4, 2021

(30) Foreign Application Priority Data
Dec. 9, 2020 (KR) 10-2020-0171375

(51) Int. Cl. H05K 13/00; G06F 1/18; H05K 13/04; H05K 1/18

(52) U.S. Cl. CPC H05K 13/0015; G06F 1/183; H05K 2201/10128; H05K 1/189; H05K 13/0469

(57) ABSTRACT

An apparatus for manufacturing a display device includes a stage on which a display panel is placed, an accommodation portion on which a display circuit board is placed, where the display circuit board is connected to the display panel, an interval adjustment portion that adjusts an interval between the stage and the accommodation portion, and a rotation driving portion that rotates the accommodation portion. When the interval adjustment portion applies a force to the display circuit board, the rotation driving portion rotates the accommodation portion.

### CROSS-REFERENCE TO RELATED APPLICATION

This application claims priority under 35 U.S.C. § 119 from Korean Patent Application No. 10-2020-0171375, filed on Dec. 9, 2020 in the Korean Intellectual Property Office, the contents of which are herein incorporated by reference in their entirety.

### 1. TECHNICAL FIELD

One or more embodiments are directed to apparatuses and methods, and more particularly, to an apparatus and method of manufacturing a display device.

### 2. DISCUSSION OF THE RELATED ART

Mobile electronic devices are widely used. Mobile electronic devices include compact electronic devices such as mobile phones as well as tablet PCs.

A mobile electronic device includes a display device to provide visual information such as an image or a video to a user and to support various functions. Recently, as other components for driving a display device are miniaturized, a portion of an electronic device taken by the display device has gradually increased, and thus a flexible structure capable of being bent is under development.

The above-described display device typically includes a display panel and a display driving circuit substrate connected to the display panel. In this state, during manufacture of a display device, to arrange the display panel in a narrow place, the display driving circuit substrate can be located at the rear surface of the display panel.

In general, when a display panel is bent, it is bent to have a preset radius of curvature in a bendable area. However, depending on errors in the device itself, the nature of a material, or a working environment, etc., in an actual process, a display panel might not be bent to have a preset radius of curvature, or a display panel can be damaged while being bent.

### SUMMARY

One or more embodiments include an apparatus and method of manufacturing a display device, in which, during bending of a display panel, damage to a display panel can be prevented when the display panel is bent to have a desired radius of curvature.

According to one or more embodiments, an apparatus for manufacturing a display device includes a stage on which a display panel is placed, an accommodation portion on which a display circuit board is placed, where the display circuit board is connected to the display panel, an interval adjustment portion that adjusts an interval between the stage and the accommodation portion, and a rotation driving portion that rotates the accommodation portion. When the interval adjustment portion applies a force to the display circuit board, the rotation driving portion rotates the accommodation portion.

In an embodiment, the apparatus further includes an elevation driving portion that is connected to the rotation driving portion and raises or lowers the rotation driving portion.

In an embodiment, the apparatus further includes a guide portion on which the stage is placed.

In an embodiment, the interval adjustment portion includes a cylinder or linear motor that is connected to the accommodation portion and linearly moves the accommodation portion.

In an embodiment, the interval adjustment portion includes a moving block, a block guide on which the moving block is placed, a block accommodation portion in which the moving block is accommodated, and a force application portion that is disposed between the block accommodation portion and the moving block and applies a force in one direction to the moving block.

In an embodiment, the interval adjustment portion includes a moving block, a block guide on which the moving block is placed, a block accommodation portion in which the moving block is accommodated, and a linear driving portion on which the moving block is placed and that moves the moving block.

In an embodiment, the stage includes a support portion that supports at least one of the display panel or the display circuit board.

According to one or more embodiments, a method of manufacturing a display device includes disposing a display panel and a display circuit board on a stage and an accommodation portion, respectively, applying a constant tension to at least one of the display panel or the display circuit board by linearly moving the accommodation portion, and bending a part of the display panel by rotating the accommodation portion.

In an embodiment, a display area of the display panel faces the stage.

In an embodiment, the method further includes forming an adhesive member on the display panel.

In an embodiment, the display panel rotates around an end portion of the adhesive member.

In an embodiment, the method further includes supporting at least one of the display panel or the display circuit board after the display panel is disposed on the stage.

In an embodiment, the method further includes aligning a position of the display panel.

In an embodiment, the method further includes adjusting an interval between the accommodation portion and the stage.

In an embodiment, an interval adjustment portion that is connected to the accommodation portion linearly moves the accommodation portion.

In an embodiment, the interval adjustment portion includes a cylinder or a linear motor that is connected to the accommodation portion and linearly moves the accommodation portion.

In an embodiment, the interval adjustment portion includes a moving block, a block guide on which the moving block is placed, a block accommodation portion in which the moving block is accommodated, and a linear driving portion on which the moving block is placed and that moves the moving block.

In an embodiment, the interval adjustment portion includes a moving block, a block guide on which the moving block is placed, a block accommodation portion in which the moving block is accommodated, and a force application portion that is disposed between the block accommodation portion and the moving block and applies a force in one direction to the moving block.

In an embodiment, tension of the display circuit board is maintained by adjusting an interval between the stage and the accommodation portion.

According to one or more embodiments, an apparatus for manufacturing a display device includes a stage on which a display panel is placed; an accommodation portion on which a display circuit board is placed, wherein the display circuit board is connected to the display panel; an interval adjustment portion that adjusts an interval between the stage and the accommodation portion; and a guide portion on which the stage is placed. The interval adjustment portion maintains a constant tension in the display circuit board by adjusting an interval between the stage and the accommodation portion.

In an embodiment, the apparatus further includes a rotation driving portion that rotates the accommodation portion; and an elevation driving portion that is connected to the rotation driving portion and raises or lowers the rotation driving portion. When the interval adjustment portion applies a force to the display circuit board, the rotation driving portion rotates the accommodation portion.

Such general and specific aspects may be implemented by using a system, a method, a computer program, or a combination of a system, a method, and/or a computer program.

### BRIEF DESCRIPTION OF THE DRAWINGS

FIG. 1 is a perspective view of an apparatus for manufacturing a display device according to an embodiment.

FIG. 2 is a front view of a display panel and a display circuit board that are both being bent by an apparatus for manufacturing a display device of FIG. 1.

FIGS. 3A to 3D are cross-sectional views of portions of an apparatus for manufacturing a display device according to one or more embodiments.

FIG. 4A is a plan view of a display device according to an embodiment.

FIG. 4B is a plan view of a display device according to an embodiment.

FIG. 5 is a cross-sectional view taken along line IV-IV′ of a display panel of FIGS. 4A and 4B.

FIGS. 6A and 6B are circuit diagrams of a display device of FIGS. 4A and 4B.

FIG. 7 is a cross-sectional view of a display device of FIGS. 4A and 4B being bent.

FIG. 8 is a cross-sectional view of a display device of FIGS. 4A and 4B being bent.

FIG. 9 is a cross-sectional view of the display device DP of FIGS. 4A and 4B being bent.

### DETAILED DESCRIPTION

Reference will now be made in detail to embodiments, examples of which are illustrated in the accompanying drawings, wherein like reference numerals may refer to like elements throughout.

In an embodiment below, it will be understood that when a component, such as a layer, a film, a region, or a plate, is referred to as being “on” another component, the component can be directly on the other component or intervening components may be present thereon.

Sizes of components in the drawings may be exaggerated for convenience of explanation.

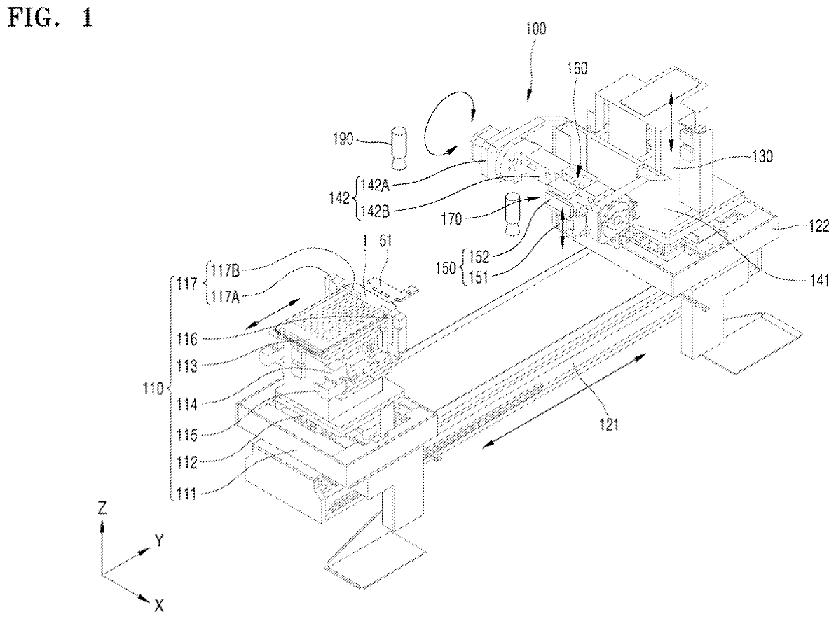

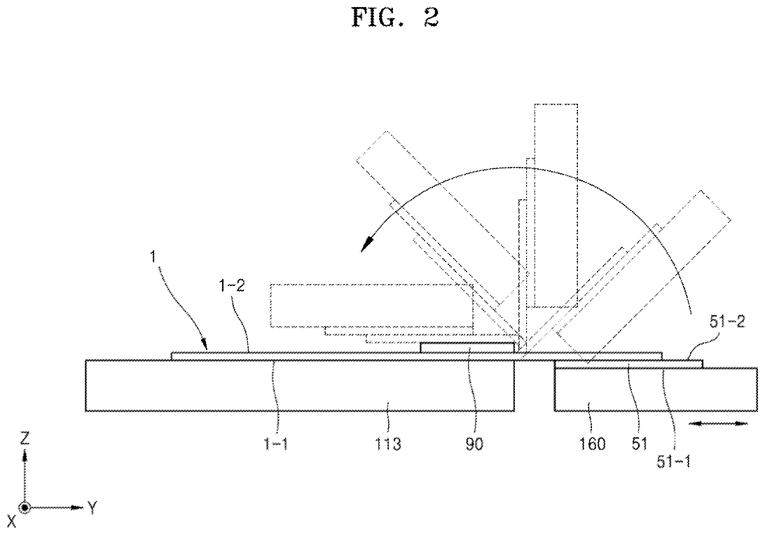

FIG. 1 is a perspective view of an apparatus 100 for manufacturing a display device according to an embodiment. FIG. 2 is a front view of a display panel and a display circuit board that are both being bent by the apparatus 100 for manufacturing a display device of FIG. 1.

Referring to FIGS. 1 and 2, in an embodiment, the apparatus 100 for manufacturing a display device includes a stage 110, a guide portion 121, a second moving block 122, an elevation driving portion 130, a support block 141, a rotation driving portion 142, a force application portion 150, an accommodation portion 160, an interval adjustment portion 170, and a vision portion 190.

In an embodiment, the stage 110 includes a first moving block 111 placed on the guide portion 121 and that performs a linear motion, an adjustment portion 112 placed on the first moving block 111 and that adjusts, in at least two directions, the position of a display panel accommodation portion 113 that is described below, and the display panel accommodation portion 113 placed on the adjustment portion 112 and on which a display panel 1 is placed. In an embodiment, the stage 110 includes a panel vision portion 114 located on a side surface of the display panel accommodation portion 113 and that captures an image of an end portion of the display panel 1, a vision driving portion 115 connected to the panel vision portion 114 and that can vary a portion of the panel vision portion 114, an optical system 116 attached onto the display panel accommodation portion 113 or the adjustment portion 112 and that refracts a path of light incident on the panel vision portion 114, and a support portion 117 placed on the display panel accommodation portion 113 or the adjustment portion 112 and that supports a part of the display panel 1 or a display circuit board 51.

The display panel accommodation portion 113 may include a vacuum chuck or an adhesive chuck. In the following description, for convenience of explanation, a case in which the display panel accommodation portion 113 is a vacuum chuck is described in detail. A hole is formed in a surface of the display panel accommodation portion 113, and the display panel 1 can be fixed by sucking a gas in the hole. In an embodiment, a pipe that connects a pump and the hole is connected to the display panel accommodation portion 113.

In an embodiment, the panel vision portion 114 includes a camera. With the camera, the panel vision portion 114 can capture an image from light being refracted through the optical system 116. For example, the panel vision portion 114 can capture an image of the end portion of the display panel 1 through the optical system 116. The image captured as above is transmitted from the panel vision portion 114 to a separate controller, etc., and the controller calculates a degree of bending of the display panel 1 based on the captured image.

In an embodiment, the vision driving portion 115 adjusts the position of the panel vision portion 114. The vision driving portion 115 can have various shapes. For example, in an embodiment, the vision driving portion 115 includes a cylinder connected to the panel vision portion 114. In an embodiment, the vision driving portion 115 includes a linear motor that is connected to the panel vision portion 114. In an embodiment, the vision driving portion 115 includes a screw connected to the panel vision portion 114, a motor that rotates the screw, and a linear motion guide disposed between the panel vision portion 114 and the adjustment portion 112. However, the vision driving portion 115 is not limited to the above described embodiments, and in other embodiments includes all apparatuses and structures in the adjustment portion 112 to allow the panel vision portion 114 to perform a linear motion.

In an embodiment, the vision driving portion 115 can focus an image received by the panel vision portion 114 by varying the position of the panel vision portion 114. For example, as the vision driving portion 115 moves the panel vision portion 114 to different positions according to the size of the display panel 1, a distance between the panel vision portion 114 and the optical system 116 is adjusted. In this case, the focus of light received by the panel vision portion 114 from the optical system 116 to can be adjusted.

In an embodiment, the optical system 116 guides light toward the panel vision portion 114 by refracting or reflecting the light. The panel vision portion 114 captures an image of the end portion of the display panel 1 accommodated on the display panel accommodation portion 113 through the optical system 116. The optical system 116 includes a filter, a mirror, a prism, a lens, etc.

In an embodiment, the support portion 117 is located adjacent to the optical system 116. The support portion 117 is placed on the display panel accommodation portion 113 or the adjustment portion 112. The support portion 117 includes a support 117a located on the display panel accommodation portion 113 or the adjustment portion 112 and a support plate 117b that can be withdrawn from the support 117a. The support plate 117b can support the display circuit board 51 or the display panel 1 by being optionally withdrawn from the support 117a or inserted into the support 117a. In an embodiment, in which the support plate 117b is rotatably connected to the support 117a, the support plate 117b rotates, and thus the support portion 117 can support the display circuit board 51. However, in the following description, for convenience of explanation, a case in which the support plate 117b is withdrawn from the support 117a or inserted into the support 117a is described.

In an embodiment, the guide portion 121 is arranged in one direction, and the stage 110 and the support block 141 are arranged to perform a linear motion. The guide portion 121 separately includes a guide driving portion that allows the stage 110 and the support block 141 to perform a linear motion. The guide driving portion includes a linear motor.

In an embodiment, the second moving block 122 is placed on the guide portion 121 and performs a linear motion along the guide portion 121 according to an operation of the guide driving portion. At least a part of the second moving block 122 includes a protrusion that can be inserted into the guide portion 121, and the guide portion 121 includes a hole into which the protruding part of the second moving block 122 can be inserted. Furthermore, the guide portion 121 includes the linear motion guide, and the second moving block 122 is coupled to a rail of the linear motion guide.

In an embodiment, the elevation driving portion 130 is located on the second moving block 122. The elevation driving portion 130 can raise or lower the support block 141. The elevation driving portion 130 may have various shapes. For example, in an embodiment, the elevation driving portion 130 includes a cylinder that is connected to the support block 141. In an embodiment, the elevation driving portion 130 includes a linear motor that is connected to the support block 141. In an embodiment, the elevation driving portion 130 includes a ball screw that is connected to the support block 141 and a motor that is connected to the ball screw. In an embodiment, the elevation driving portion 130 includes a rack gear that is connected to the support block 141, a spur gear that is connected to the rack gear, and a motor that is connected to the spur gear.

In an embodiment, the support block 141 is connected to the elevation driving portion 130 and can be raised or lowered according to an operation of the elevation driving portion 130. The rotation driving portion 142 is placed on the support block 141.

In an embodiment, the rotation driving portion 142 includes a rotational force generation portion 142a fixed on the support block 141 and that generates a rotational force, and a rotating body 142b that is rotated by the rotational force generation portion 142a. The rotational force generation portion 142a includes a motor or a motor and a decelerator. The rotating body 142b is connected to the rotational force generation portion 142a. The rotating body 142b can be rotated according to an operation of the rotational force generation portion 142a.

In an embodiment, the force application portion 150 is connected to the rotation driving portion 142. The force application portion 150 includes a force application driving force generation portion 151 fixed onto the rotating body 142b, and a force application plate 152 connected to the force application driving force generation portion 151 and that applies a force to the display circuit board 51. Since the force application driving force generation portion 151 is similar to the elevation driving portion 130 described above, a detailed description thereof is omitted.

In an embodiment, the accommodation portion 160 is located on the rotating body 142b. The display circuit board 51 is accommodated on the accommodation portion 160. The accommodation portion 160 may be an adhesive chuck or a vacuum chuck. In the following description, for convenience of explanation, a case in which the accommodation portion 160 includes a vacuum chuck is described.

In an embodiment, the interval adjustment portion 170 is placed on the rotating body 142b and allows the accommodation portion 160 to perform a linear motion. The interval adjustment portion 170 may include various apparatuses and structures that linearly move the rotating body 142b, which are described below in detail.

The vision portion 190 is placed above the guide portion 121 and can capture an image of the display panel 1. Then, based on the image captured by the vision portion 190, the position of the display panel 1 can be transmitted to the controller, and the controller can compare a preset position with the position of the display panel 1. The controller can vary the position of the display panel accommodation portion 113 by controlling the adjustment portion 112 based on a comparison result, so that the position of the display panel 1 can correspond to the preset position.

In an embodiment, when a display device is manufactured by the apparatus 100 for manufacturing a display device, the display panel 1 and the display circuit board 51 are separately manufactured, and then, the display panel 1 and the display circuit board 51 are connected to each other.

In an embodiment, after the display panel 1 and the display circuit board 51 are manufactured and connected to each other, as described above, the display panel 1 and the display circuit board 51 connected to each other are placed on the display panel accommodation portion 113. A display area DA of the display panel 1 is arranged to face the display panel accommodation portion 113. In other words, a surface in which an image of the display panel 1 is displayed is placed on the display panel accommodation portion 113.

In an embodiment, the support plate 117b is withdrawn from the support 117a and supports a part of the display circuit board 51. Then, the controller aligns the position of the display panel 1 based on the image of the display panel 1 captured by the vision portion 190. In an embodiment, an alignment mark, etc., is placed on the display panel 1, and the controller calculates the position of the display panel 1 by comparing the alignment mark with the preset position. Furthermore, the controller accurately aligns the position of the display panel 1 by comparing the alignment mark and a preset position.

In an embodiment, when the above process is completed, the guide portion 121 linearly and separately moves the stage 110 and the second moving block 122 so that the stage 110 and the second moving block 122 approach each other. When an interval between the stage 110 and the second moving block 122 is equal to a preset interval, the positions of the stage 110 and the second moving block 122 are fixed.

In an embodiment, the display circuit board 51 is placed on the accommodation portion 160. In particular, the accommodation portion 160 is initially located lower than a lower surface of the display circuit board 51 and can support the display circuit board 51 as the accommodation portion 160 is raised by the elevation driving portion 130. The upper surface of the accommodation portion 160 is located lower than an upper surface of the display panel accommodation portion 113. Then, when the display circuit board 51 is fixed onto the accommodation portion 160, the support plate 117b is inserted into the support 117a.

In an embodiment, an adhesive member 90 is disposed on the display panel 1. The adhesive member 90 is disposed on the display panel 1 after the display circuit board 51 is fixed on the accommodation portion 160, as described above. In an embodiment, the adhesive member 90 is disposed on the display panel 1 before the alignment after the display panel 1 is disposed on the display panel accommodation portion 113. In an embodiment, the adhesive member 90 is disposed on the display panel 1 before the adjustment of the interval between the stage 110 and the second moving block 122 after aligning the display panel 1.

In an embodiment, when the display panel 1 and the display circuit board 51 are disposed at the preset position as above, the interval adjustment portion adjusts an interval between the accommodation portion 160 and the display panel accommodation portion 113. In detail, the interval adjustment portion 170 applies a force to the accommodation portion 160, or when including a motor, the interval adjustment portion 170 operates the motor to generate a preset torque. The operation of the interval adjustment portion 170 is described below in detail.

In an embodiment, as the accommodation portion 160 performs a linear motion, the interval between the display panel accommodation portion 113 and the accommodation portion 160 can vary. In this case, the accommodation portion 160 applies a force to each of the display circuit board 51 and the display panel 1, and the display circuit board 51 has a constant tension. In particular, in the above case, the display panel 1 and the display circuit board 51 are flat without being curved portion due to the above tension.

In detail, in an embodiment, as described above, when the accommodation portion 160 and the display panel accommodation portion 113 are arranged at a preset position, the display circuit board 51 and the display panel 1 might not remain flat due to positional differences of the display circuit board 51 and the display panel 1, errors generated during assembly of the apparatus 100, etc. In particular, when a curved portion is generated in at least one of the display panel 1 or the display circuit board 51 arranged between the display panel accommodation portion 113 and the accommodation portion 160, the display panel 1 might not bend along a designed axis. In this case, one or both of the display panel 1 or the display circuit board 51 can be damaged because a movement path of the display circuit board 51 differs from a designed path. To address this situation, the display panel 1 should be bent in a state in which the tension of the display circuit board 51 is maintained constant. To this end, as described above, as the interval adjustment portion varies the position of the accommodation portion 160, a constant tension can be generated in the display circuit board 51.

As described above, in some embodiments, in a state in which the tension of the display circuit board 51 is maintained constant, the rotation driving portion 142 is operated to rotate the rotating body 142b, thereby rotating the display circuit board 51. For example, as illustrated in FIG. 2, the accommodation portion 160 is rotated counterclockwise. In some cases, the elevation driving portion 130 is operated to vary the position of the support block 141.

As described above, in an embodiment, in a state in which the tension of the display circuit board 51 is maintained constant, the accommodation portion 160 is rotated to rotate the display circuit board 51. A bendable area of the display panel 1 is rotated due to the rotation of the display circuit board 51. In this case, the display panel 1 is rotated with respect to the adhesive member 90.

In an embodiment, when the display circuit board 51 is rotated within a certain range, the force application driving force generation portion 151 applies a force to the display circuit board 51 by using the force application plate 152. The force application plate 152 applies a force to the display circuit board 51 at an end portion of the adhesive member 90, as shown in FIG. 2. In this case, the display panel 1 is bent to have a preset radius of curvature.

In an embodiment, when the above process is completed, bent portions of the display panel 1 are fixed to each other by the adhesive member 90. In this case, a part of a first surface 1-1 of the display panel 1 is located on the display panel accommodation portion 113, and other part of the first surface 1-1 of the display panel 1 faces upward. In this case, the first surface 1-1 is a surface on which the display area DA, described below, is formed. Furthermore, a part of a second surface 1-2 of the display panel 1 faces upward, and the other part of the second surface 1-2 of the display panel 1 faces the upward-facing part of the second surface 1-2 of the display panel 1. In this case, the adhesive member 90 is disposed between the bent parts of the second surface 1-2.

In an embodiment, a third surface 51-1 of the display circuit board 51 moves from a lower side to an upper side due to the movement of the accommodation portion 160, and a fourth surface 51-2 of the display circuit board 51 moves from an upper side to a lower side.

Accordingly, according to the apparatus 100 for manufacturing a display device and a method of manufacturing a display device according to an embodiment, as the display panel 1 is bent and fixed while maintaining the tension of the display circuit board 51, damage to at least one of the display panel 1 or the display circuit board 51 can be prevented.

According to the apparatus 100 for manufacturing a display device and a method of manufacturing a display device according to an embodiment, as the tension of the display circuit board 51 is maintained constant, it is possible to prevent the actual path and the design path from differing from each other when the display panel 1 is bent, due to design errors of a device, the properties of a material, or the conditions of a surrounding environment, such as temperature or humidity, etc.

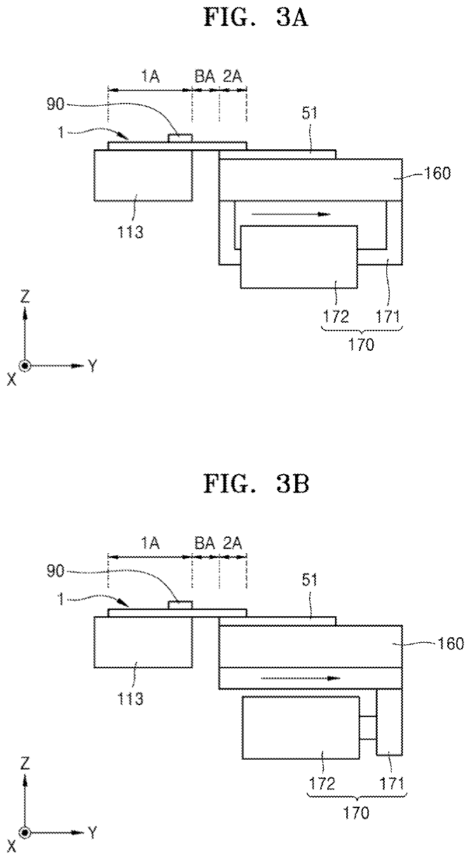

FIGS. 3A to 3D are cross-sectional views of portions of an apparatus for manufacturing a display device according to one or more embodiments.

Referring to FIGS. 3A to 3D, the interval adjustment portion 170 may have various shapes.

Referring to FIG. 3A, in an embodiment, the interval adjustment portion 170 includes a connection portion 171 connected to the accommodation portion 160 and a linear motor 172 connected to the connection portion 171 and that can linearly move the connection portion 171.

In an embodiment, the linear motor 172 is fixed on the rotating body 142b, and the connection portion 171 performs a linear motion due to the operation of the linear motor 172.

In an embodiment, the controller moves the connection portion 171 by applying power to the linear motor 172. The position of the connection portion 171 is measured and monitored in real time by using an encoder, etc., and when the position of the connection portion 171 calculated through the encoder value does not vary, the controller determines that the tension of the display circuit board 51 is constant.

In an embodiment, the display circuit board 51 is rotated by rotating the accommodation portion 160, and the display panel 1 is bent due to the rotation of the display circuit board 51. The linear motor 172 may fix the position of the connection portion 171 such that the position of the connection portion 171 is constant, or may adjust the position of the connection portion 171 such that the position of the connection portion 171 is constant.

As described above, in an embodiment, when the tension of the display circuit board 51 is maintained constant, the display panel 1 can be bent by rotating the accommodation portion 160.

Referring to FIG. 3B, in an embodiment, the interval adjustment portion 170 includes the connection portion 171 connected to the accommodation portion 160 and a cylinder 172 connected to the connection portion 171 that linearly moves the connection portion 171. The cylinder 172 is fixed on the rotating body 142b, and the accommodation portion 160 is separated from the rotating body 142b. Furthermore, the connection portion 171 is placed inside the rotating body 142b and performs a linear motion.

In an embodiment, when a constant tension is applied to the display circuit board 51 through the accommodation portion 160, the cylinder 172 varies the position of the accommodation portion 160 by varying the length of a shaft. Whether a constant tension is generated in the display circuit board 51 is checked through a change in the pressure applied to the cylinder 172. In detail, when a pressure is applied to the cylinder 172 and the display circuit board 51 is completely flat, the internal pressure of the cylinder 172 is constant at a certain moment. In this case, the controller determines that a constant tension is generated in the display circuit board 51 and then ceases operating the cylinder 172 and fixes the position of the shaft of the cylinder 172. In an embodiment, the controller maintains the internal pressure of the cylinder 172 to be constant. In an embodiment, after a pressure is provided to the cylinder 172 and a user visually checks the display circuit board 51, the pressure of the cylinder 172 is maintained constant. In an embodiment, while varying the internal pressure of the cylinder 172, the cylinder 172 is controlled by checking a degree of flatness of the display circuit board 51 through an image captured by the vision portion 190.

In an embodiment, when a constant tension has been formed in the display circuit board 51, the accommodation portion 160 is rotated.

In an embodiment, the controller can control the cylinder 172 to move the shaft to a new position by detecting the withdrawn length of the shaft of the cylinder 172. In detail, when the withdrawn length of the shaft of the cylinder 172 is determined to be greater than the withdrawn length when a constant tension is formed in the display circuit board 51 as described above, the controller controls the cylinder 172 to decrease the withdrawn length of the shaft of the cylinder 172. In contrast, when the withdrawn length of the shaft of the cylinder 172 is determined to be less than the withdrawn length when a constant tension is formed in the display circuit board 51, the controller controls the cylinder 172 to increase the withdrawn length of the shaft of the cylinder 172 so as not to apply an excessive force to the display circuit board 51.

In an embodiment, the above actions can be performed by detecting the withdrawn length of the shaft of the cylinder 172 in real time until the bending of the display panel 1 is completed. The withdrawn length of the shaft of the cylinder 172 can be calculated using a separate sensor or be based on the internal pressure of the cylinder 172. For example, the sensor can be a distance measurement sensor. Furthermore, the withdrawn length of the shaft is stored in the controller in the form of a table as a function of the internal pressure of the cylinder 172, and a pressure measurement sensor that measures the internal pressure of the cylinder 172 can be disposed on the cylinder 172 and can transmit a measured value to the controller.

Accordingly, in an embodiment, in the above case, it is possible to rotate the accommodation portion 160 while the tension of the display circuit board 51 is maintained constant.

In an embodiment, referring to FIG. 3C, the interval adjustment portion 170 includes a moving block 171, a block guide 172, a block accommodation portion 173, and a block force application portion 174.

In an embodiment, the moving block 171 is connected to the accommodation portion 160. The moving block 171 is fixedly coupled to the accommodation portion 160 through bolts, screws, etc. In an embodiment, the moving block 171 is integrally formed with the accommodation portion 160.

In an embodiment, the block guide 172 guides a motion of the moving block 171. The block guide 172 includes a linear motion guide.

In an embodiment, the block accommodation portion 173 includes a space therein that can accommodate the moving block 171 and the block guide 172. The block accommodation portion 173 may be integrally formed with or separately formed from the rotating body 142b and coupled to the rotating body 142b.

In an embodiment, the block force application portion 174 is positioned between the moving block 171 and the support portion 117. The block force application portion 174 may have various shapes. For example, the block force application portion 174 includes a coil spring. In an embodiment, the block force application portion 174 has a bar shape and includes a material such as rubber, silicon, etc.

In the above case, in an embodiment, the block force application portion 174 applies a force to the moving block 171. As the block force application portion 174 applies a force to the moving block 171 in a direction from the left to the right (a Y-axis direction) as shown in FIG. 3C, the accommodation portion 160 separates from the display panel accommodation portion 113.

As described above, in an embodiment, when the accommodation portion 160 is moved, a constant tension can be generated in the display circuit board 51. Then, when the display panel 1 is bent by rotating the accommodation portion 160, the block force application portion 174 continuously applies a force to the moving block 171 so that the position of the moving block 171 is maintained constant.

Accordingly, in an above case, as a tension is generated in the display circuit board 51, the display circuit board 51 can be prevented from being bent or crumpled.

Referring to FIG. 3D, in an embodiment, the interval adjustment portion 170 includes the moving block 171, the block guide 172, the block accommodation portion 173 and a linear driving portion 174. Since the moving block 171, the block guide 172, and the block accommodation portion 173 are the same as or similar to those described with reference to FIG. 3A, detailed descriptions thereof are omitted.

In an embodiment, the linear driving portion 174 includes a ball screw 174A and a motor 174B connected to the ball screw 174A. The ball screw 174A is connected to the moving block 171 and converts the rotational force provided by the motor 174B to a linear motion of the moving block 171. In an embodiment, the linear driving portion 174 includes the linear motor as illustrated in FIG. 3A. The linear driving portion 174 may be arranged around the block guide 172 or integrally formed with the block guide 172 to allow the moving block 171 to perform a linear motion. In an embodiment, the linear driving portion 174 includes the cylinder illustrated in FIG. 3B. The linear driving portion 174 is connected to the moving block 171 to allow the moving block 171 to perform a linear motion. However, the linear driving portion 174 is not limited to the above, and may include all apparatuses connected to the moving block 171 to allow the moving block 171 to perform a linear motion. However, in the following description, for convenience of explanation, a case in which the linear driving portion 174 includes the ball screw 174A and the motor 174B is described.

In an above case, in an embodiment, after the display circuit board 51 is placed on the accommodation portion 160, the tension of the display circuit board 51 is maintained constant by adjusting the interval between the accommodation portion 160 and the display panel accommodation portion 113. For example, power is applied to the motor 1748, and a torque of the motor 174B is detected. Power is applied to the motor 174B to generate preset torque. Then, when a current applied to the motor 174B is increased to increase the torque of the motor 174B and fold the display circuit board 51, the torque of the motor 174B is gradually increased. Then, when the current applied to the motor 174B is gradually increased, the torque of the motor 174B is not changed but is maintained at a constant value. In this case, the controller determines that the tension of the display circuit board 51 is maintained constant, and the display circuit board 51 is completely unfolded.

Then, in an embodiment, the display circuit board 51 and a part of the display panel 1 are rotated by rotating the accommodation portion 160. In this case, the tension of the display circuit board 51 is maintained constant by maintaining the torque of the motor 174B unchanged. The above action is performed in real time during the rotation of the accommodation portion 160.

In the above case, in an embodiment, since the display circuit board 51 is rotated while tension is applied to the display circuit board 51, it is possible to bend the display panel 1 to have a certain radius of curvature in a bendable area BA of the display panel 1. Furthermore, when bending the display panel 1, it is possible to prevent a radius of curvature in the bendable area BA from exceeding a designed value.

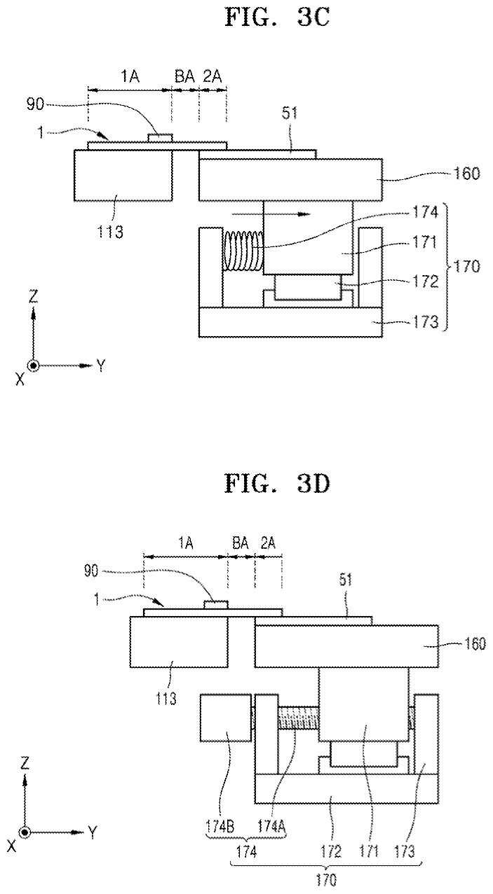

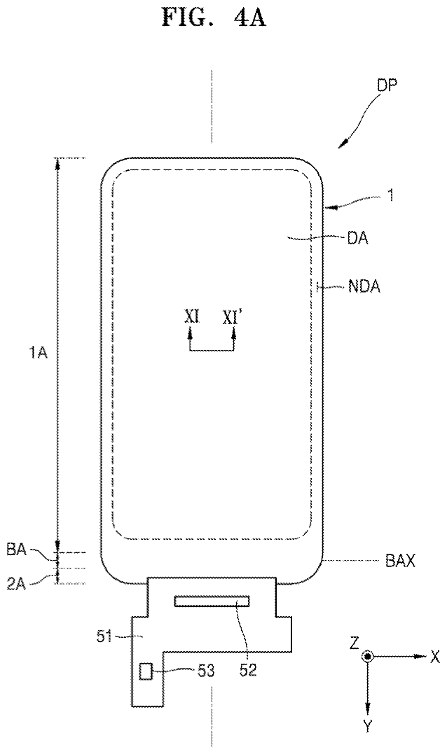

FIG. 4A is a plan view of a display device DP according to an embodiment.

Referring to FIG. 4A, in an embodiment, the display device DP includes the display panel 1, the display circuit board 51, a display driving portion 52, and a touch sensor driving portion 53. The display panel 1 is a light-emitting display panel that includes a light-emitting element. For example, the display panel 1 may include an organic light-emitting display panel that uses an organic light-emitting diode that includes an organic light-emitting layer, or an ultracompact light-emitting diode display panel that uses a micro-light-emitting diode (micro LED), or a quantum dot light-emitting display panel that uses a quantum dot light-emitting diode that includes a quantum dot light-emitting layer, or an inorganic light-emitting display panel that uses an inorganic light-emitting element that includes an inorganic semiconductor.

In an embodiment, the display panel 1 includes a flexible display panel that can be easily bent, folded, or rolled. For example, the display panel 1 may include a foldable display panel that can be folded and unfolded, a curved display panel with a curved display surface, a bent display panel in which an area other than a display surface is bent, a rollable display panel that can be rolled or unrolled, or a stretchable display panel.

In an embodiment, the display panel 1 includes a transparent display panel so that an object or a background located at a lower surface of the display panel 1 can be seen from an upper surface of the display panel 1. Alternatively, in an embodiment, the display panel 1 includes a reflective display panel that can reflect an object or a background of the upper surface of the display panel 1.

In an embodiment, the display panel 1 as above includes the display area DA in which an image is displayed and a peripheral area NDA that surrounds the display area DA. The display area includes a plurality of pixels. A separate driving circuit, a pad, etc., can be located in the peripheral area NDA.

Furthermore, in an embodiment, the display panel 1 includes a first area 1A in the display area DA, the bendable area BA connected to the first area 1A and that can be bent with respect to a bending axis BAX, and a second area 2A connected to the bendable area BA and the display circuit board 51. The second area 2A and the bendable area BA are part of the peripheral area NDA, and no image is displayed therein.

In an embodiment, the display circuit board 51 is attached to at one side edge of the display panel 1. One side of the display circuit board 51 is attached to the one side edge of the display panel 1 by using an anisotropic conductive film.

In an embodiment, the display driving portion 52 is located on the display circuit board 51. The display driving portion 52 receives control signals and power voltages, and generates and outputs signals and voltages that drive the display panel 1. The display driving portion 52 is formed as an integrated circuit (IC).

In an embodiment, the display circuit board 51 is attached to the display panel 1. The display circuit board 51 and the display panel 1 are attached to each other by using an anisotropic conductive film. The display circuit board 51 may include a flexible printed circuit board (FPCB) that is bendable or a composite printed circuit board that includes a rigid printed circuit board (RPCB) that is not bendable.

In an embodiment, the touch sensor driving portion 53 is located on the display circuit board 51. The touch sensor driving portion 53 is formed as an IC. The touch sensor driving portion 53 is attached onto the display circuit board 51. The touch sensor driving portion 53 is electrically connected to touch electrodes of a touchscreen layer of the display panel 1 through the display circuit board 51.

In an embodiment, the touchscreen layer of the display panel 1 can detect a users touch input by using at least one of various touch methods, such as a resistive touch type, a capacitive touch type, etc. For example, when the touchscreen layer of the display panel 1 senses a users touch input by a capacitive screen type method, the touch sensor driving portion 53 determines the occurrence of a user's touch by applying driving signals to driving electrodes of the touch electrodes, and detecting voltages charged in mutual capacitance between the driving electrodes and sensing electrodes through the sensing electrodes of the touch electrodes. The users touch may be a contact touch or a proximity touch. A contact touch refers to an object such as a users finger, a pen, etc., directly contacting a cover member on the touchscreen layer. A proximity touch refers to an object such as a user's finger, a pen, etc., being located in close proximity on the cover member, such as hovering. The touch sensor driving portion 53 transmits sensor data to a main processor according to the detected voltages, and the main processor analyzes the sensor data and calculates touch coordinates where the touch input is generated.

In an embodiment, a power supply portion that supplies a driving voltage that drives the pixels, a scan driving portion, and the display driving portion 52 of the display panel 1 are further located on the display circuit board 51. Alternatively, in an embodiment, the power supply portion is incorporated with the display driving portion 52, and the display driving portion 52 and the power supply portion are provided as one IC.

FIG. 4B is a plan view of a display device DP according to an embodiment.

Referring to FIG. 4B, in an embodiment, the display device DP includes the display panel 1, the display circuit board 51, the display driving portion 52, the touch sensor driving portion 53, and a flexible film 54. The display panel 1, the display driving portion 52, and the touch sensor driving portion 53 are similar to those described in FIG. 4A.

In an embodiment, the display panel 1 includes the display area DA and the peripheral area NDA, and also includes the first area 1A in which the display area DA is located, the bendable area BA connected to the first area 1A and that can be bent, and the second area 2A connected to the bendable area BA. A width of the bendable area BA is less than the length of the side of the first area 1A to which the bendable area BA is connected. In other words, the width of the bendable area BA measured in an X-axis direction of FIG. 4B decreases from the first area 1A toward the second area 2A and then is constant.

In an embodiment, the flexible film 54 is attached to one side edge of the display panel 1. One side of the flexible film 54 is attached to one side edge of the display panel 1 by using an anisotropic conductive film. The flexible film 54 is bendable.

In an embodiment, the display driving portion 52 is located on the flexible film 54. The display driving portion 52 receives control signals and power voltages, and generates and outputs signals and voltages that drive the display panel 1. The display driving portion 52 is formed as an IC. The display driving portion 52 is disposed directly on the flexible film 54, and the display driving portion 52 and the flexible film 54 are connected to each other through an anisotropic conductive film.

In an embodiment, the display circuit board 51 is attached to the other side of the flexible film 54. The other side of the flexible film 54 is attached to an upper surface of the display circuit board 51 by using an anisotropic conductive film. The display circuit board 51 may include an FPCB (flexible printed circuit board) that is bendable or a composite printed circuit board that includes a RPCB (rigid printed circuit board) that is not bendable.

In an embodiment, in the display device DP as above, the display panel 1 can be bent by the apparatus 100 for manufacturing a display device illustrated in FIGS. 1 to 3D. In this case, at least one of the display circuit board 51 or the flexible film 54 may be positioned in the accommodation portion 160, and the tension of one of the display circuit board 51 or the flexible film 54 is maintained constant by adjusting the position of the accommodation portion 160.

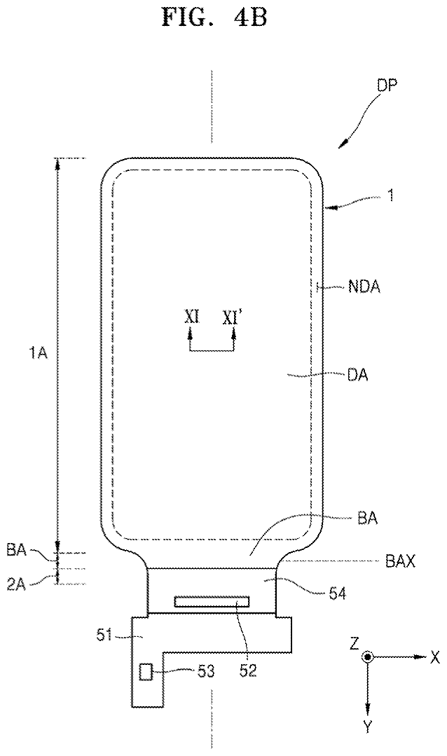

FIG. 5 is a cross-sectional view of the display panel 1 taken along line IV-IV′ of FIGS. 4A and 4B.

Referring to FIG. 5, in an embodiment, the display panel 1 includes a substrate 10, a buffer layer 11, a circuit layer, and a display component layer, which are stacked.

As described above, in an embodiment, the substrate 10 includes an insulating material such as glass, quartz, or a polymer resin, etc. The substrate 10 is a flexible substrate capable of being bent, folded, or rolled, etc.

In an embodiment, the buffer layer 11 is disposed on the substrate 10 to prevent or reduce infiltration of a foreign material, moisture, or external air from under the substrate 10, and provides a planarized surface on the substrate 10. The buffer layer 11 may include an inorganic material such as an oxide or a nitride, an organic material, or an organic/inorganic complex, and may have a single layer or a multilayer structure of an inorganic material and an organic material. A barrier layer that prevents infiltration of external air may be provided between the substrate 10 and the buffer layer 11. In some embodiments, the buffer layer 11 includes silicon oxide (SiO₂) or a silicon nitride (SiNₓ). The buffer layer 11 includes a first buffer layer 11a and a second buffer layer 11b, which are stacked.

In an embodiment, the circuit layer is disposed on the buffer layer 11, and includes a pixel circuit (PC), a first gate insulating layer 12, a second gate insulating layer 13, an interlayer insulating layer 15, and a planarization layer 17. The PC includes a thin film transistor TFT and a storage capacitor Cst.

In an embodiment, the thin film transistor TFT is disposed above the buffer layer 11. The thin film transistor TFT include a first semiconductor layer A1, a first gate electrode G1, a first source electrode S1, and a first drain electrode D1. The thin film transistor TFT is connected to an organic light-emitting diode OLED and drives a main OLED.

In an embodiment, the first semiconductor layer A1 is disposed on the buffer layer 11, and includes poly silicon. In an embodiment, the first semiconductor layer A1 includes amorphous silicon. In an embodiment, the first semiconductor layer A1 includes an oxide of at least one of indium (in), gallium (Ga), stannum (Sn), zirconium (Zr), vanadium (V), hafnium (Hf), cadmium (Cd), germanium (Ge), chromium (Cr), titanium (Ti) or zinc (Zn). The first semiconductor layer A1 includes a channel region, and a source region and drain region, in which impurities are doped.

In an embodiment, the first gate insulating layer 12 covers the first semiconductor layer A1 and the buffer layer 11. The first gate insulating layer 12 includes an inorganic insulating material such as at least one of SiO₂, SiNₓ, silicon oxynitride (SiON), an aluminum oxide (Al₂O₃), a titanium oxide (TiO₂), a tantalum oxide (Ta₂O₅), a hafnium oxide (HfO₂), or a zinc oxide (ZnO₂), etc. The first gate insulating layer 12 may have a single layer or a multilayer structure that includes at least one of the above-described inorganic insulating materials.

In an embodiment, the first gate electrode G1 is disposed above the first gate insulating layer 12 and overlaps the first semiconductor layer A1. The first gate electrode G1 may include one or more of molybdenum (Mo), aluminum (Al), copper (Cu), or titanium (Ti), etc., and may have a single layer or a multilayer structure. For example, the first gate electrode G1 may have a single layer of Mo.

In an embodiment, the second gate insulating layer 13 is disposed on the first gate insulating layer 12 and covers the first gate electrode G1. The second gate insulating layer 13 includes an inorganic insulating material such as SiO₂, SiNₓ, SiON, Al₂O₃, TiO₂, Ta₂O₅, HfO₂, or ZnO₂, etc. The second gate insulating layer 13 may have a single layer or a multilayer structure that includes at least one of the above-described inorganic insulating materials.

In an embodiment, a first upper electrode CE2 of the main storage capacitor Cst is disposed on the second gate insulating layer 13.

In an embodiment, the first upper electrode CE2 overlaps with the first gate electrode G1 thereunder. The first gate electrode G1 and the first upper electrode CE2 overlap each other with the second gate insulating layer 13 interposed therebetween and form the main storage capacitor Cst. The first gate electrode G1 is a first lower electrode CE1 of the main storage capacitor Cst.

In an embodiment, the first upper electrode CE2 includes at least one of Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), or Cu, and may have a single layer or a multilayer structure of the above-described materials.

In an embodiment, the interlayer insulating layer 15 is disposed on the second gate insulating layer 13 and covers the first upper electrode CE2. The interlayer insulating layer 15 includes at least one of SiO₂, SiNₓ, SiON, Al₂O₃, TiO₂, Ta₂O₅, HfO₂, or ZnO₂, etc. The interlayer insulating layer 15 may have a single layer or a multilayer structure that includes the above-described inorganic insulating materials.

In an embodiment, the first source electrode S1 and the first drain electrode D1 are disposed on the interlayer insulating layer 15. The first source electrode S1 and the first drain electrode D1 each include a conductive material that includes at least one of Mo, Al, Cu, or Ti, etc., and may have a multilayer or a single layer structure that includes the above materials. For example, the first source electrode S1 and the first drain electrode D1 each have a multilayer structure of Ti/Al/Ti.

In an embodiment, the planarization layer 17 is disposed on the interlayer insulating layer 15 and covers the first source electrode S1 and the first drain electrode D1. The planarization layer 17 has a flat upper surface so that a pixel electrode 21 disposed thereon can be flat.

In an embodiment, the planarization layer 17 may include an organic material or an inorganic material, and may have a single layer structure or a multilayer structure. The planarization layer 17 may include a general purpose polymer such as at least one of benzocyclobutene (BCB), a polyimide, hexamethyldisiloxane (HMDSO), polymethylmethacrylate (PMMA), polystyrene, polymer derivatives with a phenolic group, an acrylic polymer, an imide-based polymer, an aryl ether-based polymer, an amide-based polymer, a fluorine-based polymer, a p-xylene-based polymer, or a vinyl alcohol-based polymer, etc. The planarization layer 17 may include an inorganic insulating material such as at least one of SiO₂, SiNₓ, SiON, Al₂O₃, TiO₂, Ta₂O₅, HfO₂, or ZnO₂, etc. After the planarization layer 17 is formed, to provide the planarization layer 17 with a flat upper surface, chemical mechanical polishing is performed on the upper surface of the planarization layer 17.

In an embodiment, the pixel electrode 21 is formed on the planarization layer 17. The planarization layer 17 has a via hole that exposes one of the first source electrode S1 or the first drain electrode D1 of the main thin film transistor TFT, and the pixel electrode 21 contacts the first source electrode S1 or the first drain electrode D1 via the via hole to be electrically connected to the main thin film transistor TFT.

In an embodiment, the pixel electrode 21 includes a conductive oxide such as at least one of an indium tin oxide (ITO), an indium zinc oxide (IZO), a zinc oxide (ZnO), an indium oxide (In₂O₃), an indium gallium oxide (IGO), or an aluminum zinc oxide (AZO). The pixel electrode 21 includes a reflective film that includes at least one of Ag, Mg, Al, Pt, Pd, Au, Ni, Nd, Ir or Cr, or a compound thereof. For example, the pixel electrode 21 has a structure in which films that include at least one of ITO, IZO, ZnO, or In₂O₃ are provided above or under the reflective film. For example, the pixel electrode 21 has a stacked structure of ITO/Ag/ITO.

In an embodiment, a pixel definition layer 19 is disposed on the planarization layer 17 and includes a first opening OP1 that covers an edge of the pixel electrode 21 and exposes a central portion of the pixel electrode 21. A light-emitting area of an organic light-emitting diode (OLED), that is, the size and shape of a subpixel is defined by the first opening OP1.

In an embodiment, since the pixel definition layer 19 increases a distance between the edge of the pixel electrode 21 and a counter electrode 23 above the pixel electrode 21, the generation of an arc, etc., at the edge of the pixel electrode 21 can be prevented. The pixel definition layer 19 includes an organic insulating material such as at least one of a polyimide, a polyamide, an acryl resin, benzocyclobutene, HMDSO, or phenol resin, etc., by a method such as spin coating, etc.

In an embodiment, a light-emitting layer 22b is disposed in the first opening OP1 of the pixel definition layer 19 to correspond to the pixel electrode 21. The light-emitting layer 22b may include a polymer material or a low molecular weight material, and may emit red, green, blue, or white light.

In an embodiment, an organic functional layer 22e is disposed above and/or under the light-emitting layer 22b and on the pixel definition layer 19. The organic functional layer 22e includes a first functional layer 22a and/or a second functional layer 22c. Either of the first functional layer 22a or the second functional layer 22c may be omitted.

In an embodiment, the first functional layer 22a is disposed under the light-emitting layer 22b. The first functional layer 22a includes an organic material in a single layer or a multilayer structure. In an embodiment, the first functional layer 22a is a hole transport layer (HTL) that has a single layer structure. Alternatively, in an embodiment, the first functional layer 22a includes a hole injection layer (HIL) and a hole transport layer (HTL). The first functional layer 22a is integrally formed and corresponds to the OLEDs in the display area DA.

In an embodiment, the second functional layer 22c is disposed above the light-emitting layer 22b. The second functional layer 22c includes an organic material in a single layer or a multilayer structure. The second functional layer 22c includes an electron transport layer (ETL) and/or an electron injection layer (EIL). The second functional layer 22c is integrally formed and corresponds to the OLEDs in the display area DA.

In an embodiment, the counter electrode 23 is disposed on the second functional layer 22c. The counter electrode 23 includes a conductive material having a low work function. For example, the counter electrode 23 includes a (semi-) transparent layer that includes at least one of Ag, Mg, Al, Pt, Pd, Au, Ni, Nd, Ir, Cr, lithium (Li) or Ca, or an alloy thereof, etc. Alternatively, in an embodiment, the counter electrode 23 further includes at least one of ITO, IZO, ZnO or In₂O₃ on the (semi-) transparent layer. The counter electrode 23 is integrally formed and corresponds to the OLEDs in the display area DA.

In an embodiment, layers from the pixel electrode 21 to the counter electrode 23 in the display area DA form the main OLED.

In an embodiment, an upper layer 50 that includes an organic material is formed on the counter electrode 23. The upper layer 50 protects the counter electrode 23 and simultaneously increases light extraction efficiency. The upper layer 50 includes an organic material that has a higher refractive index than the counter electrode 23. Alternatively, in an embodiment, the upper layer 50 includes stacked layers that have different refractive indexes. For example, the upper layer 50 is a stacked structure of a high refractive index layer/a low refractive index layer/a high refractive index layer. The refractive index of a high refractive index layer is about 1.7 or more, and the refractive index of a low refractive index layer is about 1.3 or less.

In an embodiment, the upper layer 50 additionally includes LiF. Alternatively, in an embodiment, the upper layer 50 additionally includes an inorganic insulating material such as SiO₂ or SiNₓ. The upper layer 50 may be omitted as necessary. However, in the following description, for convenience of explanation, a case in which the upper layer 50 is disposed on the counter electrode 23 is described.

In an embodiment, the display device DP as above includes a thin film encapsulation layer that shields the upper layer 50.

In an embodiment, the thin film encapsulation layer is disposed on the upper layer 50 and directly contacts the upper layer 50. The thin film encapsulation layer covers a part of the display area DA and a peripheral area that is a non-display area NDA, thereby preventing infiltration of external moisture and oxygen. The thin film encapsulation layer includes at least one organic encapsulation layer and at least one inorganic encapsulation layer. In the following description, for convenience of explanation, a case in which the thin film encapsulation layer includes a first inorganic encapsulation layer, an organic encapsulation layer, and a second inorganic encapsulation layer that are sequentially stacked on the upper surface of the upper layer 50 is described.

In the above case, in an embodiment, the first inorganic encapsulation layer covers the counter electrode 23 and includes a silicon oxide, a silicon nitride, and/or a silicon oxynitride. Since the first inorganic encapsulation layer is formed along a structure thereunder, an upper surface of the inorganic encapsulation layer may not be flat. The organic encapsulation layer covers the first inorganic encapsulation layer, and unlike the first inorganic encapsulation layer, the upper surface of the organic encapsulation layer is approximately flat. In detail, the upper surface of the organic encapsulation layer is approximately flat in a portion corresponding to the display area DA. The organic encapsulation layer includes one or more materials selected from polyethylene terephthalate, polyethylene naphthalate, polycarbonate, polyimide, polyethylene sulfonate, polyoxymethylene, polyarylate, or hexamethyldisiloxane. The second inorganic encapsulation layer covers the organic encapsulation layer, and includes a silicon oxide, a silicon nitride, and/or a silicon oxynitride.

In an embodiment, a touchscreen layer is disposed on the thin film encapsulation layer.

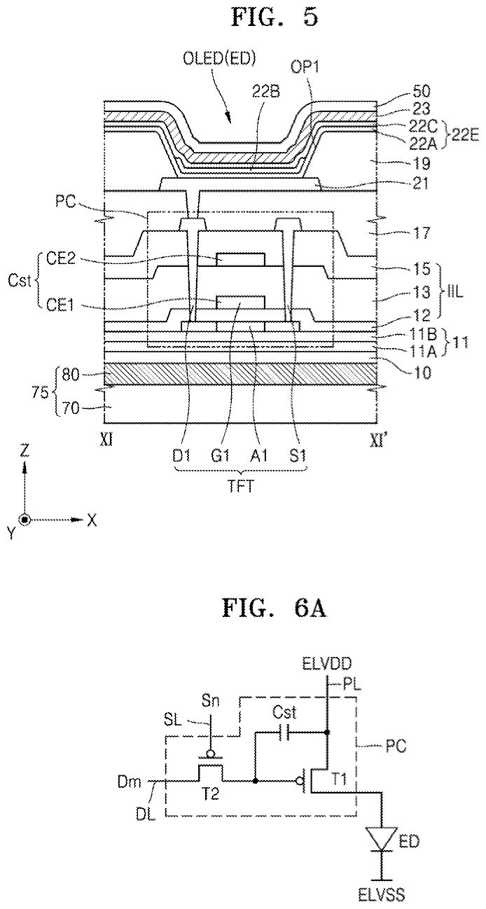

FIGS. 6A and 6B are circuit diagrams of the display device DP of FIGS. 4A and 4B.

Referring to FIGS. 6A and 6B, in an embodiment, the PC is connected to an emission device ED, such as an organic light-emitting diode (OLED), to control emission of subpixels. The PC includes a driving thin film transistor T1, a switching thin film transistor T2, and a storage capacitor Cst. The switching thin film transistor T2 is connected to a scan line SL and a data line DL, and transmits a data signal Dm to the driving thin film transistor T1, the data signal Dm being received through the data line DL according to a scan signal Sn received through the scan line SL.

In an embodiment, the storage capacitor Cst is connected to the switching thin film transistor T2 and a driving voltage line PL, and stores a voltage that is equivalent to a difference between a voltage received from the switching thin film transistor T2 and a driving voltage ELVDD received from the driving voltage line PL.

In an embodiment, the driving thin film transistor T1 is connected to the driving voltage line PL and the storage capacitor Cst, and controls a driving current that flows to the emission device ED from the driving voltage line PL and that corresponds to a value of the voltage stored in the storage capacitor Cst. A counter electrode of the emission device ED is provided with a common voltage ELVSS. The emission device ED emits light having a certain luminance due to the driving current.

Although FIG. 6A illustrates a case in which the PC includes two thin film transistors and one storage capacitor, embodiments of the disclosure are not limited thereto.

Referring to FIG. 6B, in an embodiment, the PC includes the driving thin film transistor T1, the switching thin film transistor T2, a compensation thin film transistor T3, a first initialization thin film transistor T4, an operation control thin film transistor T5, an emission control thin film transistor T6, and a second initialization thin film transistor T7.

Although FIG. 6B illustrates a case in which signal lines SL, SL−1, SL+1, EL, and DL, an initialization voltage line VL, and the driving voltage line PL are provided for each PC, embodiments of the disclosure are not limited thereto. In other embodiments, at least one of the signal lines SL, SL−1, SL+1, EL, and DL, or/and the initialization voltage line VL are shared by neighboring pixel circuits.

In an embodiment, a drain electrode of the driving thin film transistor T1 is electrically connected to the emission device ED via the emission control thin film transistor T6. The driving thin film transistor T1 receives the data signal Dm according to a switching operation of the switching thin film transistor T2 and supplies a driving current to the emission device ED.

In an embodiment, a gate electrode of the switching thin film transistor T2 is connected to the scan line SL, and a source electrode thereof is connected to the data line DL. A drain electrode of the switching thin film transistor T2 is connected to a source electrode of the driving thin film transistor T1 and to the driving voltage line PL via the operation control thin film transistor T5.

In an embodiment, the switching thin film transistor T2 is turned on in response to the scan signal Sn received through the scan line SL and performs a switching operation to transmit the data signal Dm received through the data line DL to the source electrode of the driving thin film transistor T1.

In an embodiment, a gate electrode of the compensation thin film transistor T3 is connected to the scan line SL. A source electrode of the compensation thin film transistor T3 is connected to the drain electrode of the driving thin film transistor T1 and to a pixel electrode of the emission device ED via the emission control thin film transistor T6. A drain electrode of the compensation thin film transistor T3 is connected to an electrode of the storage capacitor Cst, a source electrode of the first initialization thin film transistor T4, and a gate electrode of the driving thin film transistor T1. The compensation thin film transistor T3 is turned on in response to the scan signal Sn received through the scan line SL, and diode-connects the driving thin film transistor T1 by connecting the gate electrode and the drain electrode of the driving thin film transistor T1.

In an embodiment, a gate electrode of the first initialization thin film transistor T4 is connected to a previous scan line SL-1. A drain electrode of the first initialization thin film transistor T4 is connected to the initialization voltage line VL. The source electrode of the first initialization thin film transistor T4 is connected to an electrode of the storage capacitor Cst, the drain electrode of the compensation thin film transistor T3, and the gate electrode of the driving thin film transistor T1. The first initialization thin film transistor T4 is turned on in response to a previous scan signal Sn-1 received through the previous scan line SL-1, and performs an initialization operation to initialize a voltage of the gate electrode of the driving thin film transistor T1 by transmitting an initialization voltage Vint to the gate electrode of the driving thin film transistor T1.

In an embodiment, a gate electrode of the operation control thin film transistor T5 is connected to an emission control line EL. A source electrode of the operation control thin film transistor T5 is connected to the driving voltage line PL. A drain electrode of the operation control thin film transistor T5 is connected to the source electrode of the driving thin film transistor T1 and the drain electrode of the switching thin film transistor T2.

In an embodiment, a gate electrode of the emission control thin film transistor T6 is connected to the emission control line EL. A source electrode of the emission control thin film transistor T6 is connected to the drain electrode of the driving thin film transistor T1 and the source electrode of the compensation thin film transistor T3. A drain electrode of the emission control thin film transistor T6 is electrically connected to the pixel electrode of the emission device ED. The operation control thin film transistor T5 and the emission control thin film transistor T6 are simultaneously turned on in response to an emission control signal En received through the emission control line EL, and thus the driving voltage ELVDD is transmitted to the emission device ED so that a driving current flows in the emission device ED.

In an embodiment, a gate electrode of the second initialization thin film transistor T7 is connected to a next scan line SL+1. A source electrode of the second initialization thin film transistor T7 is connected to the pixel electrode of the emission device ED. A drain electrode of the second initialization thin film transistor T7 is connected to the initialization voltage line VL. The second initialization thin film transistor T7 is turned on in response to a next scan signal Sn+1 received through the next scan line SL+1, and initializes the pixel electrode of the emission device ED.

FIG. 6B illustrates a case in which the first initialization thin film transistor T4 and the second initialization thin film transistor T7 are connected to the previous scan line SL-1 and the next scan line SL+1, respectively. However, embodiments of the disclosure are not limited thereto. In an embodiment, the first initialization thin film transistor T4 and the second initialization thin film transistor T7 are both connected to the previous scan line SL-1 and driven according to the previous scan signal Sn-1.

In an embodiment, one electrode of the storage capacitor Cst is connected to the driving voltage line PL. The other electrode of the storage capacitor Cst is connected to the gate electrode of the driving thin film transistor T1, the drain electrode of the compensation thin film transistor T3, and the source electrode of the first initialization thin film transistor T4.

In an embodiment, a counter electrode, such as a cathode, of the emission device ED, is provided with a common voltage ELVSS. The emission device ED emits light by receiving a driving current from the driving thin film transistor T1.

Embodiments of the PC are not limited to those shown and described with reference to FIGS. 6A and 6B, and in other embodiments, the number of thin film transistors and storage capacitors and the circuit design itself may be changed in various ways.

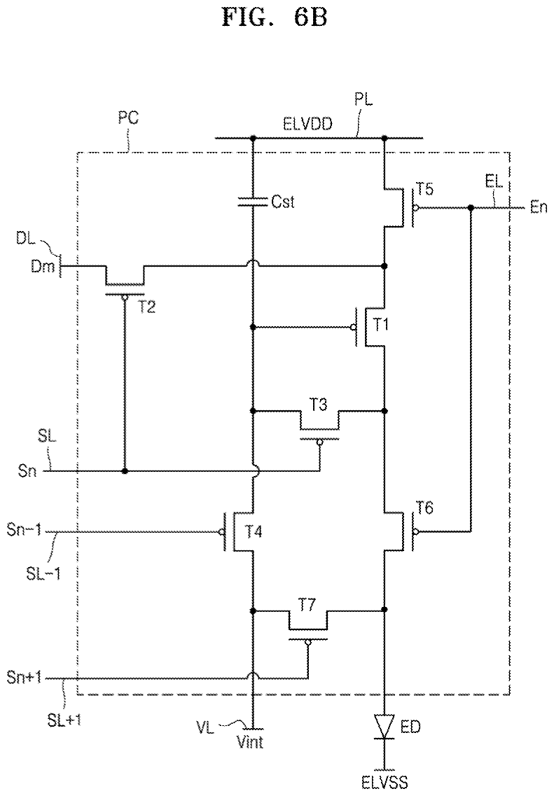

FIG. 7 is a cross-sectional view of the display device DP of FIGS. 4A and 4B being bent.

Referring to FIG. 7, in an embodiment, when the display panel is bent, the adhesive member 90 is formed on the substrate 10 of the display panel 1. In other words, as the adhesive member 90 is formed at a bent portion of the substrate 10, one surface of the substrate 10 in the first area 1A of the display panel 1 and one surface of the substrate 10 in the second area 2A of the display panel 1 are fixedly attached to each other.

In an embodiment, a protection film 75 is disposed on the substrate 10, and the protection film 75 in the first area 1A and the protection film 75 in the second area 2A are fixedly attached to each other through the adhesive member 90. In the following description, for convenience of explanation, a case in which the protection film 75 is disposed on the substrate 10 and thus the protection film 75 in the first area 1A and the protection film 75 in the second area 2A are each attached to the adhesive member 90 is described.

In an embodiment, the protection film 75 includes a protection film base 70 and an adhesive layer 80. The protection film base 70 includes polyethylene terephthalate (PET) or polyimide (PI). Furthermore, the adhesive layer 80 includes various adhesive materials. The adhesive layer 80 is formed on the entire surface of the substrate 10, and the protection film base 70 is formed on the adhesive layer 80 and then partially removed, thereby forming an the opening portion 750P. In another embodiment, a part of the protection film base 70 and a part of the adhesive layer 80 are removed, thereby forming the opening portion 750P. Both of the protection film base 70 and the adhesive layer 80 are removed from the opening portion 750P.

In an embodiment, the substrate 10 is bent in the bendable area BA. The protection film base 70 of the protection film 75, which protects the lower surface of the substrate 10, is stiff. Accordingly, since the protection film base 70 is inflexible, if the protection film base covers the bendable area BA, as the substrate 10 is bent, delamination can occur between the protection film base 70 and the substrate 10. However, in a display device according to a present embodiment, as the protection film 75 has the opening portion 750P that corresponds to the bendable area BA, delamination is effectively prevented.

Although the protection film 75 is described as having the opening portion 750P that corresponds to the bendable area BA and as being attached to the lower surface of the substrate 10 in the first area 1A and the second area 2A, embodiments of the disclosure are not limited thereto. For example, in other embodiments, the protection film 75 corresponds to at least a part of the first area 1A of the substrate 10. In other words, the protection film 75 is omitted from the second area 2A of the substrate 10.

Furthermore, although, in one or more embodiments, the substrate 10 is illustrated as being bent with respect to the bending axis BAX such that a part of the lower surface in the first area 1A and at least a part of the lower surface in the second area 2A face each other, embodiments of the disclosure are not limited thereto. In other embodiments, various modifications are available. For example, the lower surface in the second area 2A does not face the lower surface in the first area 1A, because a radius of curvature in the bendable area BA is less than that illustrated in the drawings, or the area of the bendable area BA is relatively small.

In the above case, the substrate 10 is bent by rotating the display circuit board 51 when tension is generated in the display circuit board 51 as described above.

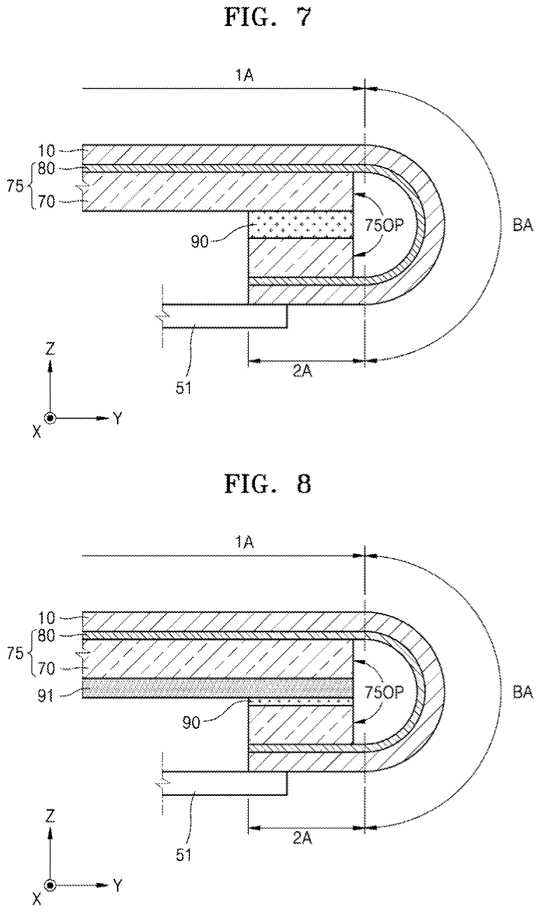

FIG. 8 is a cross-sectional view of the display device DP of FIGS. 4A and 4B being bent.

Referring to FIG. 8, in an embodiment, after bending the substrate 10, etc., a cushion layer 91 is further formed in an area where the first area 1A and the second area 2A face each other. In other words, the cushion layer 91 is formed on a part of the first area 1A of the protection film base 70 and the second area 2A of the protection film base 70 in contact therewith. The cushion layer 91 is formed in a space where the first area 1A and the second area 2A are separated from each other after the substrate 10 is bent, etc., and supports the display panel 1 and absorbs impacts. The cushion layer 91 includes an elastic material. However, embodiments of the display device DP are not limited to the above, and in other embodiments, the cushion layer 91 is attached to the protection film base 70 before the substrate 10 is bent.

In an embodiment, the adhesive member 90 is formed between the cushion layer 91 and the protection film base 70 of the second area 2A to fix the cushion layer 91 and the protection film base 70.

In an embodiment, the substrate 10 is bent by rotating the display circuit board 51, as described above, when tension is generated in the display circuit board 51.

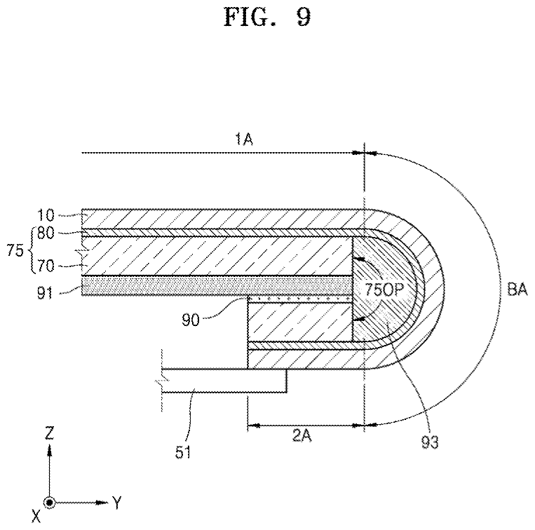

FIG. 9 is a cross-sectional view of the display device DP of FIGS. 4A and 4B being bent.

Referring to FIG. 9, in an embodiment, the display device DP further includes a filling 93 disposed in the opening portion 750P. The filling 93 is used together with the cushion layer 91. In this case, the filling 93 and the cushion layer 91 are formed after the substrate 10 is bent. In an embodiment, the substrate 10 is bent after the filling 93 and the cushion layer 91 are formed. However, embodiments of the disclosure are not limited to the above, and the filling 93 and the cushion layer 91 may be formed by various methods.

In an embodiment, since the adhesive member 90 is formed on the cushion layer 91, as described above, the cushion layer 91 is fixed to the protection film base 70 in the second area 2A by the adhesive member 90.

In an embodiment, the substrate 10 is bent by rotating the display circuit board 51, as described above, when tension is generated in the display circuit board 51.

According to an apparatus and method of manufacturing a display device according to one or more embodiments, a display circuit board may be attached at an accurate position.

According to an apparatus and method of manufacturing a display device according to one or more embodiments, a substrate of a display panel may be bent when tension of a display circuit board is maintained.

According to an apparatus and method of manufacturing a display device according to one or more embodiments, implementation of constant quality may be possible.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, the apparatus comprising:
a stage on which a display panel is placed;
an accommodation portion on which a display circuit board is placed, wherein the display circuit board is connected to the display panel;
an interval adjustment portion that adjusts an interval between the stage and the accommodation portion; and
a rotation driving portion that rotates the accommodation portion,
wherein, when the interval adjustment portion applies a force to the display circuit board, the rotation driving portion rotates the accommodation portion.

2. The apparatus of claim 1, further comprising an elevation driving portion that is connected to the rotation driving portion and raises or lowers the rotation driving portion.

3. The apparatus of claim 1, further comprising a guide portion on which the stage is placed.

4. The apparatus of claim 1, wherein the interval adjustment portion comprises a cylinder or linear motor that is connected to the accommodation portion and linearly moves the accommodation portion.

5. The apparatus of claim 1, wherein the interval adjustment portion comprises:
a moving block that is connected to the accommodation portion and moves;
a block guide on which the moving block is placed;
a block accommodation portion in which the moving block is accommodated; and
a force application portion that is disposed between the block accommodation portion and the moving block and that applies a force in one direction to the moving block.

6. The apparatus of claim 1, wherein the interval adjustment portion comprises:
a moving block that is connected to the accommodation portion and moves;
a block guide on which the moving block is placed;
a block accommodation portion in which the moving block is accommodated; and
a linear driving portion on which the moving block is placed and that moves the moving block.

7. The apparatus of claim 1, wherein the stage includes a support portion that supports at least one of the display panel or the display circuit board.

8. A method of manufacturing a display device, the method comprising:
disposing a display panel and a display circuit board on a stage and an accommodation portion, respectively;
applying a constant tension to at least one of the display panel or the display circuit board by linearly moving the accommodation portion; and
bending a part of the display panel by rotating the accommodation portion.

9. The method of claim 8, wherein a display area of the display panel faces the stage.

10. The method of claim 8, further comprising forming an adhesive member on the display panel.

11. The method of claim 10, wherein the display panel rotates around an end portion of the adhesive member.

12. The method of claim 8, further comprising supporting at least one of the display panel or the display circuit board after the display panel is disposed on the stage.

13. The method of claim 8, further comprising aligning a position of the display panel.

14. The method of claim 8, further comprising adjusting an interval between the accommodation portion and the stage.

15. The method of claim 8, wherein an interval adjustment portion that is connected to the accommodation portion linearly moves the accommodation portion.

16. The method of claim 15, wherein the interval adjustment portion comprises a cylinder or a linear motor that is connected to the accommodation portion and that linearly moves the accommodation portion.

17. The method of claim 15, wherein the interval adjustment portion comprises:
a moving block that is connected to the accommodation portion and moves;
a block guide on which the moving block is placed;
a block accommodation portion in which the moving block is accommodated; and
a linear driving portion on which the moving block is placed and that moves the moving block.

18. The method of claim 15, wherein the interval adjustment portion comprises:
a moving block that is connected to the accommodation portion and moves;
a block guide on which the moving block is placed;
a block accommodation portion in which the moving block is accommodated; and
a force application portion that is placed between the block accommodation portion and the moving block and applies a force in one direction to the moving block.

19. The method of claim 8, wherein tension of the display circuit board is maintained by adjusting an interval between the stage and the accommodation portion.

20. An apparatus for manufacturing a display device, the apparatus comprising:
a stage on which a display panel is placed;
an accommodation portion on which a display circuit board is placed, wherein the display circuit board is connected to the display panel;
an interval adjustment portion that adjusts an interval between the stage and the accommodation portion; and
a guide portion on which the stage is placed,
wherein the interval adjustment portion maintains a constant tension in the display circuit board by adjusting an interval between the stage and the accommodation portion.

21. The apparatus of claim 20, further comprising:
a rotation driving portion that rotates the accommodation portion; and
an elevation driving portion that is connected to the rotation driving portion and raises or lowers the rotation driving portion,
wherein, when the interval adjustment portion applies a force to the display circuit board, the rotation driving portion rotates the accommodation portion.
